(19) United States
(12) Patent Application Publication
(10) Pub. No.: US 2014/0273402 A1
(43) Pub. Date: Sep. 18, 2014

(54) METHOD FOR CUTTING WAFER

(71) Applicant: SURETECH TECHNOLOGY CO., LTD., Taichung City (TW)

(72) Inventors: Hung-Wen TSAI, Taichung City (TW); Chun-Ting CHEN, Taichung City (TW)

(73) Assignee: SURETECH TECHNOLOGY CO., LTD., Taichung City (TW)

(21) Appl. No.: 14/156,995

(22) Filed: Jan. 16, 2014

(30) Foreign Application Priority Data
Mar. 18, 2013 (TW) 102109563

(51) Int. Cl. H01L 21/822

(52) U.S. Cl. CPC H01L 21/822
USPC 438/463

(57) ABSTRACT

A method for cutting wafers includes following steps. A silicon wafer is provided. A metal layer is formed on a top side of the silicon wafer. A bump layer is formed on the metal layer. A backside grinding tape is attached on the bump layer. A bottom side of the silicon wafer is half cut to form a cutting race. The bottom side of the silicon wafer is ground, so that a thickness of the silicon wafer is a predetermined thickness and only partial cutting race remains. The backside grinding tape is removed. A dicing tape is attached on the bottom side of the silicon wafer. The metal layer is cut by a laser. The metal layer is communicated with the cutting race. The manufacturing cost is reduced without crumbling or cracking. The chippings on the top or bottom side of the silicon wafer can be removed.

### BACKGROUND OF THE INVENTION

1. Field of the Invention

The present invention relates to a wafer manufacture process, and especially relates to a method for cutting silicon wafers.

2. Description of the Related Art

FIGS. 1A and 1B are schematic diagrams showing the related art cutting process for silicon wafer. A plurality of conventional integrated circuits are manufactured on a silicon wafer 10a. The silicon wafer 10a will be cut into a plurality of dice after the integrated circuits are manufactured or after the bumps are formed on the silicon wafer 10a.

In the related art silicon wafer cutting process, the top side of the silicon wafer 10a is cut upward. The silicon wafer cutting process is a very precise technology. The rotational speed of the spindle of the cutter is between 30000 to 60000 rpm. The cutting precision must be high (3 um to 205 mm) because the distance between the dice is very short (about 2 mil) and the dice are very weak. Diamond blades are used for cutting. The dice are cut and separated by grinding. A lot of chippings will be generated on the silicon wafer 10a when grinding and cutting. Therefore, the silicon wafer 10a must be rinsed with water when cutting to avoid polluting the silicon wafer 10a.

There are still many issues have to be noted during the cutting process for the silicon wafer 10a besides the problems mentioned above. For examples, the dice must be cut completed but the tape for carrying the silicon wafer 10a cannot be cut (damaged). The dice must be cut along the cutting lines between the dice (the cutting path cannot be deviated or serpentine) when cutting. The dice cannot be crumbled or cracked after cutting. In the related art cutting process, firstly the silicon wafer 10a is cut by a diamond blade 20a (with a thicker blade) to form a first cutting race 30a. A location b1 of the silicon wafer 10a shown in FIG. 1A is easily crumbled or cracked. Then, a bottom side of the first cutting race 30a is cut by a diamond blade 40a (with a thinner blade) to form a second cutting race 50a. A location b2 and a location b3 shown in FIG. 1B are easily crumbled or cracked. Moreover, a tape 60a for carrying the silicon wafer 10a tends to be cut (damaged).

### SUMMARY OF THE INVENTION

In order to solve the above-mentioned problems, an object of the present invention is to provide a method for cutting wafers. The bottom side of the silicon wafer is cut and then ground (or ground and then cut). After that, the top side of the silicon wafer is cut. The manufacturing cost is reduced without crumbling or cracking. The chippings on the top or bottom side of the silicon wafer can be removed.

In order to achieve the object of the present invention mentioned above, the method for cutting wafers includes following steps. A silicon wafer is provided. A metal layer is formed on a top side of the silicon wafer. A bump layer is formed on the metal layer. A backside grinding tape is attached on the bump layer. A bottom side of the silicon wafer is cut to form a first cutting race. A bottom side of the first cutting race is cut by a second blade to form a second cutting race. The bottom side of the silicon wafer is ground, so that a thickness of the silicon wafer is a predetermined thickness and only the second cutting race remains. The backside grinding tape is removed. A dicing tape is attached on the bottom side of the silicon wafer. The metal layer is cut by a laser, so that the metal layer is communicated with the second cutting race. Therefore, the silicon wafer is cut into dice.

Moreover, the metal layer is formed in a seal-ring type by the printing process. The bump layer with a plurality of solder bumps is formed on the metal layer by bump forming process. The second cutting race is near the metal layer.

In order to achieve the object of the present invention mentioned above, another method for cutting wafers includes following steps. A silicon wafer is provided. A metal layer is formed on a top side of the silicon wafer. A bump layer is formed on the metal layer. A backside grinding tape is attached on the bump layer. A bottom side of the silicon wafer is ground, so that a thickness of the silicon wafer is a predetermined thickness. The bottom side of the silicon wafer is cut to form a cutting race. The backside grinding tape is removed. A dicing tape is attached on the bottom side of the silicon wafer. The metal layer is cut by a laser, so that the metal layer is communicated with the cutting race. Therefore, the silicon wafer is cut into dice.

Moreover, the metal layer is formed in a seal-ring type by the printing process. The bump layer with a plurality of solder bumps is formed on the metal layer by bump forming process. The cutting race is near the metal layer.

### BRIEF DESCRIPTION OF DRAWING

FIG. 1A shows a schematic diagram showing that the related art silicon wafer is cut.

FIG. 1B shows a schematic diagram showing that the related art silicon wafer is cut.

FIG. 2 shows a flow chart of the method for cutting the silicon wafer of the present invention.

FIG. 3 shows a schematic diagram of the metal layer and the bump layer of the present invention.

FIG. 4 shows a schematic diagram showing that the backside grinding tape is attached on the bump layer.

FIG. 5 shows a schematic diagram showing that the first cutting race is completed.

FIG. 6 shows a schematic diagram showing that the second cutting race is completed.

FIG. 7 shows a schematic diagram showing that the bottom side of the silicon wafer is ground.

FIG. 8 shows a schematic diagram showing that the dicing tape is attached on the bottom side of the silicon wafer.

FIG. 9 shows a schematic diagram showing that the silicon wafer is cut by the laser.

FIG. 10 shows a schematic diagram showing that the silicon wafer is cut into two dice.

FIG. 11 shows the flow chart of the method for cutting the silicon wafer according to another embodiment of the present invention.

FIG. 12 shows a schematic diagram of the metal layer and the bump layer of the present invention.

FIG. 13 shows a schematic diagram showing that the backside grinding tape is attached on the bump layer.

FIG. 14 shows a schematic diagram showing that the bottom side of the silicon wafer is ground.

FIG. 15 shows a schematic diagram showing that the cutting race is completed.

FIG. 16 shows a schematic diagram showing that the dicing tape is attached on the bottom side of the silicon wafer.

FIG. 17 shows a schematic diagram showing that the silicon wafer is cut by the laser.

FIG. 18 shows a schematic diagram showing that the silicon wafer is cut into two dice.

### DETAILED DESCRIPTION OF THE INVENTION

FIG. 2 shows a flow chart of the method for cutting the silicon wafer of the present invention. FIG. 3 shows a schematic diagram of the metal layer and the bump layer of the present invention. FIG. 4 shows a schematic diagram showing that the backside grinding tape is attached on the bump layer. FIG. 5 shows a schematic diagram showing that the first cutting race is completed. FIG. 6 shows a schematic diagram showing that the second cutting race is completed. FIG. 7 shows a schematic diagram showing that the bottom side of the silicon wafer is ground. FIG. 8 shows a schematic diagram showing that the dicing tape is attached on the bottom side of the silicon wafer. FIG. 9 shows a schematic diagram showing that the silicon wafer is cut by the laser. FIG. 10 shows a schematic diagram showing that the silicon wafer is cut into two dice. The method for cutting silicon wafers includes following steps in sequence. Firstly, a silicon wafer 1 (as shown in FIG. 3) is provided (step 100).

A seal-ring metal layer 2 is formed (printed) on a top side of the silicon wafer 1 (step 102).

A bump layer 3 with a plurality of solder bumps (as shown in FIG. 3) is formed on the metal layer 2 by bump forming process (step 104).

A backside grinding tape 4 (as shown in FIG. 4) is attached on the bump layer 3 (step 106).

The silicon wafer 1 is reversed after the backside grinding tape 4 is attached on the bump layer 3. A bottom side of the silicon wafer 1 is half cut by a first blade 5 (with a thicker blade) to form a first cutting race 11 (as shown in FIG. 5) (step 108).

A bottom side of the first cutting race 11 is cut by a second blade 6 (with a thinner blade) to form a second cutting race 12 (as shown in FIG. 6) near the metal layer 2 (step 110).

The bottom side of the silicon wafer 1 is ground by a grinder (not shown in FIG. 2-10), so that a thickness of the silicon wafer 1 is a predetermined thickness and only the second cutting race 12 remains (the first cutting race 11 is ground completely) (step 112). The chippings, crumbling or serpentines on the bottom side of the silicon wafer 1 are removed by grinding (as shown in FIG. 7).

The backside grinding tape 4 is removed after the bottom side of the silicon wafer 1 is ground. A dicing tape 7 (as shown in FIG. 8) is attached on the bottom side of the silicon wafer 1 (step 114).

The metal layer 2 is cut by a laser 8, so that the metal layer 2 is communicated with the second cutting race 12 (as shown in FIG. 9 and FIG. 10) (step 116). Therefore, the silicon wafer 1 is cut into dice.

The manufacturing cost for the process mentioned above is reduced. The chippings on the top or bottom side of the silicon wafer 1 can be removed.

FIG. 11 shows the flow chart of the method for cutting the silicon wafer according to another embodiment of the present invention. FIG. 12 shows a schematic diagram of the metal layer and the bump layer of the present invention. FIG. 13 shows a schematic diagram showing that the backside grinding tape is attached on the bump layer. FIG. 14 shows a schematic diagram showing that the bottom side of the silicon wafer is ground. FIG. 15 shows a schematic diagram showing that the cutting race is completed. FIG. 16 shows a schematic diagram showing that the dicing tape is attached on the bottom side of the silicon wafer. FIG. 17 shows a schematic diagram showing that the silicon wafer is cut by the laser. FIG. 18 shows a schematic diagram showing that the silicon wafer is cut into two dice. The method for cutting silicon wafers according to another embodiment of the present includes following steps in sequence. Firstly, a silicon wafer 1 (as shown in FIG. 12) is provided (step 200).

A seal-ring metal layer 2 is formed (printed) on a top side of the silicon wafer 1 (step 202).

A bump layer 3 with a plurality of solder bumps (as shown in FIG. 12) is formed on the metal layer 2 by bump forming process (step 204).

A backside grinding tape 4 (as shown in FIG. 13) is attached on the bump layer 3 after the bump layer 3 is formed (step 206).

A bottom side of the silicon wafer 1 is ground by a grinder (not shown in FIG. 11˜18), so that a thickness of the silicon wafer 1 is a predetermined thickness (as shown in FIG. 14) (step 208).

The bottom side of the silicon wafer 1 is half cut by a blade 9 to form a cutting race 91 (as shown in FIG. 15) near the metal layer 2 (step 210).

The backside grinding tape 4 is removed after the bottom side of the silicon wafer 1 is half cut. A dicing tape 7 (as shown in FIG. 16) is attached on the bottom side of the silicon wafer 1 (step 212).

The metal layer 2 is cut by a laser 8, so that the metal layer 2 is communicated with the cutting race 91 (as shown in FIG. 17 and FIG. 18) (step 214). Therefore, the silicon wafer 1 is cut into dice.

The manufacturing cost for the process mentioned above is reduced. The chippings on the top or bottom side of the silicon wafer 1 can be removed.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for cutting wafer comprising:
(a) providing a silicon wafer;
(b) forming a metal layer on a top side of the silicon wafer;
(c) forming a bump layer on the metal layer;
(d) attaching a backside grinding tape on the bump layer;
(e) cutting a bottom side of the silicon wafer to form a first cutting race;
(f) cutting a bottom side of the first cutting race by a second blade to form a second cutting race;
(g) grinding the bottom side of the silicon wafer, so that a thickness of the silicon wafer is a predetermined thickness and only the second cutting race remains;
(h) removing the backside grinding tape and attaching a dicing tape on the bottom side of the silicon wafer; and
(i) cutting the metal layer by a laser, so that the metal layer is communicated with the second cutting race.

2. The method for cutting wafer in claim 1, wherein in step b, the metal layer is formed in a seal-ring type by printing process.

3. The method for cutting wafer in claim 2, wherein in step c, the bump layer with a plurality of solder bumps is formed on the metal layer by bump forming process.

4. The method for cutting wafer in claim 3, wherein in step f, the second cutting race is near the metal layer.

5. A method for cutting wafer comprising:
(a) providing a silicon wafer;
(b) forming a metal layer on a top side of the silicon wafer;
(c) forming a bump layer on the metal layer;
(d) attaching a backside grinding tape on the bump layer;
(e) grinding a bottom side of the silicon wafer, so that a thickness of the silicon wafer is a predetermined thickness;
(f) cutting the bottom side of the silicon wafer to form a cutting race;
(g) removing the backside grinding tape and attaching a dicing tape on the bottom side of the silicon wafer; and
(h) cutting the metal layer by a laser, so that the metal layer is communicated with the cutting race.

6. The method for cutting wafer in claim 5, wherein in step b, the metal layer is formed in a seal-ring type by printing process.

7. The method for cutting wafer in claim 6, wherein in step c, the bump layer with a plurality of solder bumps is formed on the metal layer by bump forming process.

8. The method for cutting wafer in claim 7, wherein in step f, the cutting race is near the metal layer.
